(19) United States
(12) Patent Application Publication
(10) Pub. No.: US 2015/0008492 A1
(43) Pub. Date: Jan. 8, 2015

(54) SEMICONDUCTOR DEVICE AND METHOD OF MANUFACTURING SAME

(71) Applicant: KABUSHIKI KAISHA TOSHIBA, Tokyo (JP)

(72) Inventors: Masahiro Koike, Tokyo (JP); Yuuichi Kamimuta, Yokkaichi (JP); Tsutomu Tezuka, Tsukuba (JP)

(21) Appl. No.: 14/497,928

(22) Filed: Sep. 26, 2014

Related U.S. Application Data
(63) Continuation of application No. PCT/JP2012/078882, filed on Nov. 7, 2012.

(30) Foreign Application Priority Data
Mar. 27, 2012 (JP) 2012-071409

(51) Int. Cl. H01L 29/16; H01L 21/324; H01L 21/02; H01L 21/265; H01L 29/78; H01L 29/167

(52) U.S. Cl. CPC H01L 29/16; H01L 29/78; H01L 29/167; H01L 21/02532; H01L 21/26513; H01L 21/324
USPC 257/288; 438/197

(57) ABSTRACT

According to one embodiment, a semiconductor device of a junctionless structure includes a semiconductor layer of a first conductivity type. A pair of source/drain electrodes at a distance is on the semiconductor layer. A gate insulating film is on the semiconductor layer between the source/drain electrodes. A gate electrode is on the gate insulating film. The semiconductor layer has two or more kinds of impurities. One kind of the two or more kinds of impurities is an element selected from a group of chalcogens, and another kind of the two or more kinds of impurities is a first conductivity type impurity.

### CROSS-REFERENCE TO RELATED APPLICATIONS

This application is a Continuation Application of PCT Application No. PCT/JP2012/078882, filed Nov. 7, 2012 and based upon and claiming the benefit of priority from Japanese Patent Application No. 2012-071409, filed Mar. 27, 2012, the entire contents of all of which are incorporated herein by reference.

### FIELD

Embodiments relate to a semiconductor device which has an impurity diffusion area and method of manufacturing the same.

### BACKGROUND

In development of a Ge-MOSFET, which is expected as a device of a next generation, an impurity diffusion area such as an n⁺-Ge layer is generally formed by introducing an n-type impurity by ion implantation into a Ge substrate. At this time, in order to reduce defects produced by the ion implantation to activate the impurity electrically, a heat treatment (annealing) is necessary.

In the heat treatment after the ion implantation, in order to activate the impurity sufficiently, a heat treatment at a high temperature (>450° C.) is necessary. The high temperature heat treatment, however, may increase, for example, the density of the interface state between a gate insulating film and Ge substrate, which may deteriorate characteristics of the device.

### BRIEF DESCRIPTION OF THE DRAWINGS

FIG. 1A is a figure showing a profile of an impurity concentration of a Ge layer with P ion-implanted;

FIG. 1B is a figure showing a profile an electron concentration of the Ge layer with P ion-implanted;

FIG. 2A is a figure showing a profile of an impurity concentration of a Ge layer with S ion-implanted;

FIG. 2B is a figure showing a profile of an electron concentration of the Ge layer with S ion-implanted;

FIG. 3A is a figure showing a profile of an impurity concentration of a Ge layer with Se ion-implanted;

FIG. 3B is a figure showing a profile of an electron concentration of the Ge layer with Se ion-implanted;

FIG. 4A is a figure showing a profile of an impurity concentration of a Ge layer with Te ion-implanted;

FIG. 4B is a figure showing a profile of an electron concentration of the Ge layer with Te ion-implanted;

FIG. 5A is a figure showing a profile of an impurity concentration of a Ge layer with P and S ion-implanted;

FIG. 5B is a figure showing a profile of an electron concentration of the Ge layer with P and S ion-implanted;

FIG. 6A is a figure showing a profile of an impurity concentration of a Ge layer with P and Se ion-implanted;

FIG. 6B is a figure showing a profile of an electron concentration of the Ge layer with P and Se ion-implanted;

FIG. 7A is a figure showing a profile of an impurity concentration of a Ge layer with P and Te ion-implanted;

FIG. 7B is a figure showing a profile of an electron concentration of the Ge layer with P and Te ion-implanted;

FIG. 8A is a figure showing a profile of an impurity concentration of a Ge layer with S, Be, and Te ion-implanted (heat treatment temperature of 250° C.);

FIG. 8B is a figure showing a profile of an impurity concentration of a Ge layer with S. Se, and Te ion-implanted (heat treatment temperature of 350° C.);

FIG. 8C is a figure showing a profile of an impurity concentration of a Ge layer with S, Be, and Te ion-implanted (heat treatment temperature of 450° C.);

FIG. 9 is a figure showing a profile of an electron concentration of the Ge layer with S, Se, and Te ion-implanted;

FIG. 10 is a figure showing the relationship between an annealing temperature of a Ge layer with various elements introduced, and the maximum concentration of electrons;

FIG. 11 is a sectional view showing a schematic structure of a Ge-MOSFET according to a first embodiment;

FIG. 12A is a sectional view showing a process for manufacturing a Ge-MOSFET according to the first embodiment;

FIG. 12B is a sectional view showing the process for manufacturing the Ge-MOSFET according to the first embodiment;

FIG. 12C is a sectional view showing the process for manufacturing the Ge-MOSFET according to the first embodiment;

FIG. 13A shows a schematic structure of a nonvolatile semiconductor memory device according to a second embodiment and a sectional view along the channel length direction;

FIG. 13B shows a schematic structure of a nonvolatile semiconductor memory device according to the second embodiment, and a sectional view along the channel width direction;

FIG. 14 is a sectional view showing a schematic structure of a junctionless transistor according to a third embodiment; and

FIG. 15 is a sectional view showing a modification of the third embodiment.

### DETAILED DESCRIPTION

A purpose of one embodiment is to provide a semiconductor device which allows an impurity introduced into a semiconductor layer to be electrically activated at a low temperature to contribute to improvement of characteristics of a device element, and a method of manufacturing the same.

According to one embodiment, a semiconductor device of a functionless structure comprising: a semiconductor layer of a first conductivity type; a pair of source/drain electrodes at a distance on the semiconductor layer; a gate insulating film on the semiconductor layer between the source/drain electrodes; a gate electrode on the gate insulating film, wherein the semiconductor layer has two or more kinds of impurities, one kind of the two or more kinds of impurities is an element selected from a group of chalcogens, and another kind of the two or more kinds of impurities is a first conductivity type impurity.

According to one embodiment, as an impurity introduced into a semiconductor layer for forming an impurity diffusion area, an impurity of a required conductivity type is introduced and an element selected from chalcogens is introduced, which allows the impurity to be activated sufficiently even at a low temperature. This can improve characteristics of a device element.

Before description is made of the embodiments, a fundamental idea for solving problems will be described.

The inventors performed various experiments and research into formation of an n-type impurity diffusion area in a Ge substrate. As a result, they discovered that introducing a chalcogen (S, Sc, or Te) along with P as an n-type impurity to Ge results in formation of an n⁺-Ge layer with a concentration of electrons higher than would be in a case of using only P.

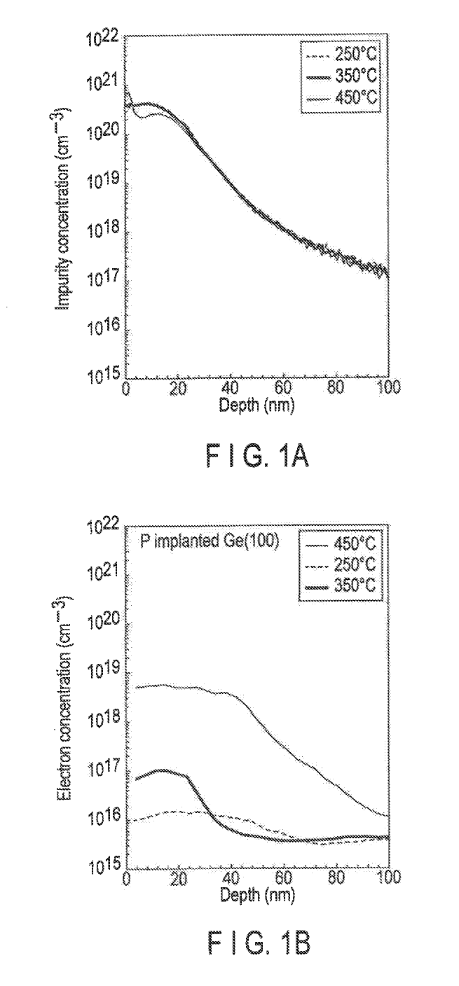

For a case of using only P as an n-type impurity implanted into a Ge substrate, a profile of an impurity concentration is as shown in FIG. 1A and a profile of an electron concentration is as shown in FIG. 1B. At this time, the P dose wa 1×10¹⁵ cm⁻², and the acceleration energy was 10 keV. When a heat treatment was performed for one minute in an N₂ atmosphere at temperatures of 250,350, and 450° C., the impurity concentration profile hardly changed in accordance with the temperature except for a vicinity of the surface as shown in FIG. 1A. That is, it can be seen that diffusion hardly occurs except for a vicinity of the surface. The electron concentration profile increases in a vicinity of the surface in accordance with the increase of the temperature as shown in FIG. 1B. That is, it can be seen that the electron concentration increases near the surface. The maximum concentration for the case of the heat treatment temperature of 450° C. is 5.6×1.0¹⁸ cm⁻³.

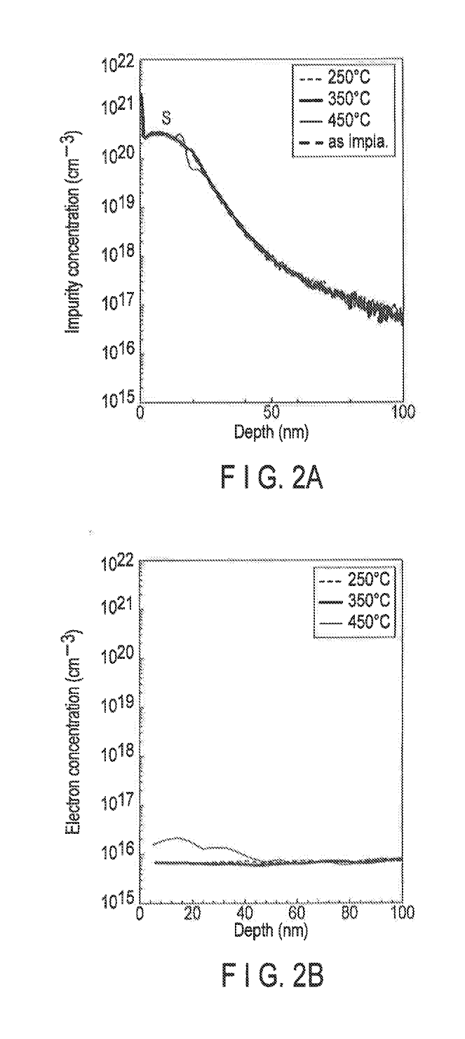

In contrast, for a case of only S as a chalcogen implanted into a Ge substrate, a profile of an impurity concentration is as shown in FIG. 2A and a profile of an electron concentration is as shown in FIG. 2B. The S dose was 5×10¹⁴ cm⁻². An acceleration energy of 10 keV was chosen to allow the projected range to match with P implantation.

When a heat treatment was performed for one minute in an N₂ atmosphere at temperatures of 250, 350, and 450° C., the impurity concentration profile hardly changed with the temperature as in the case of P as shown in FIG. 2A. Moreover, as shown in FIG. 2B, it was found that the electron concentration increased only in the 450° C. case, and hardly increased at 350° C. or 250° C. The maximum concentration for the 450° C. case is 2.1×10¹⁶ cm⁻³.

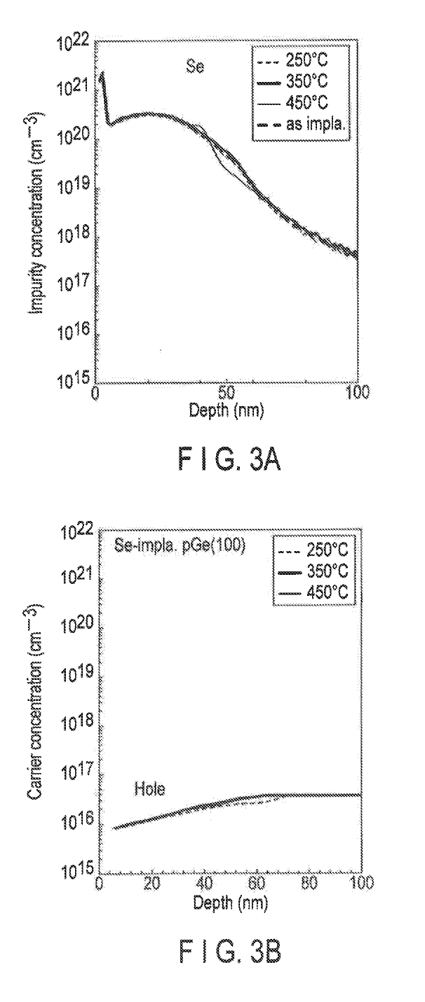

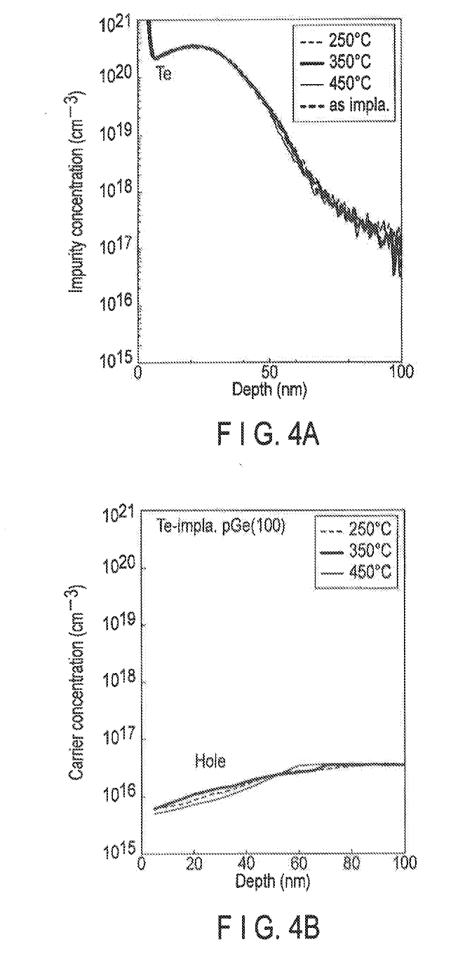

Moreover, for a case of only Se as a chalcogen implanted into a Ge substrate, a profile of an impurity concentration is as shown in FIG. 3A and a profile of a carrier concentration is as shown in FIG. 3B. Furthermore, for a case of only Te as a chalcogen implanted into a Ge substrate, a profile of an impurity concentration is as shown in FIG. 4A and a profile of a carrier concentration is as shown in FIG. 4B. With these chalcogens, impurity profiles hardly change in accordance with the temperature as in the P and S cases. Furthermore, it was found that generation of electrons was not observed even at a high temperature.

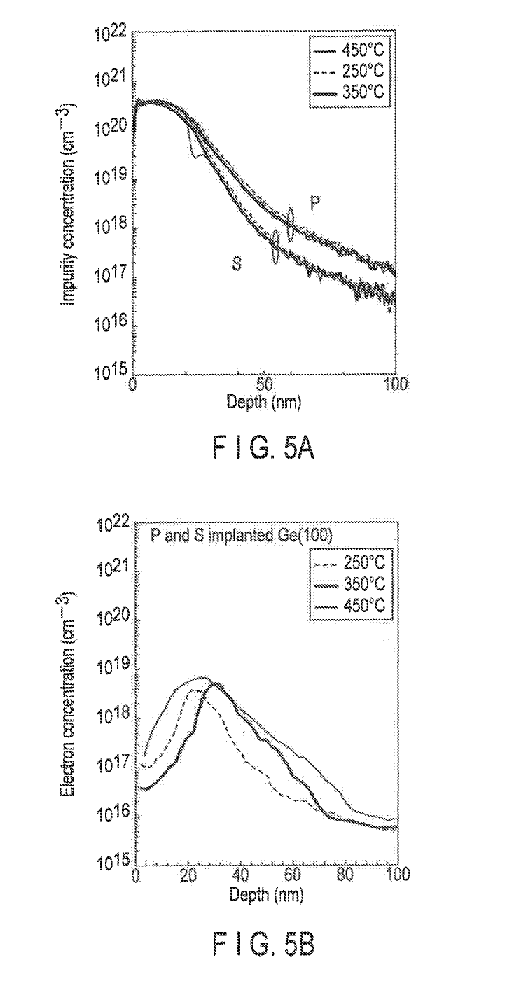

In contrast, when S is implanted into a Ge substrate along with P (with the same doses and acceleration energies as only P case and only S case), a profile of an impurity concentration hardly changes except for a vicinity of the surface at each temperature, as shown in FIG. 5A. However, as shown in FIG. 5B, it was found that the electron concentration profile changes in accordance with the temperature, as well as the depth. In addition, it was observed that the electron concentration increases even at a low temperature, such as 350° C. or 250° C., as can be seen from comparison with the FIG. 1B.

That is, although the electron concentration. hardly increases at a temperature of 250° C. or 350° C. for a case of only P introduced, it was found that the electron concentration, which was already high, increases from a low temperature (250° C.) for a case of P introduced along with S. The maximum concentration is 6.9×10¹⁸ cm⁻³.

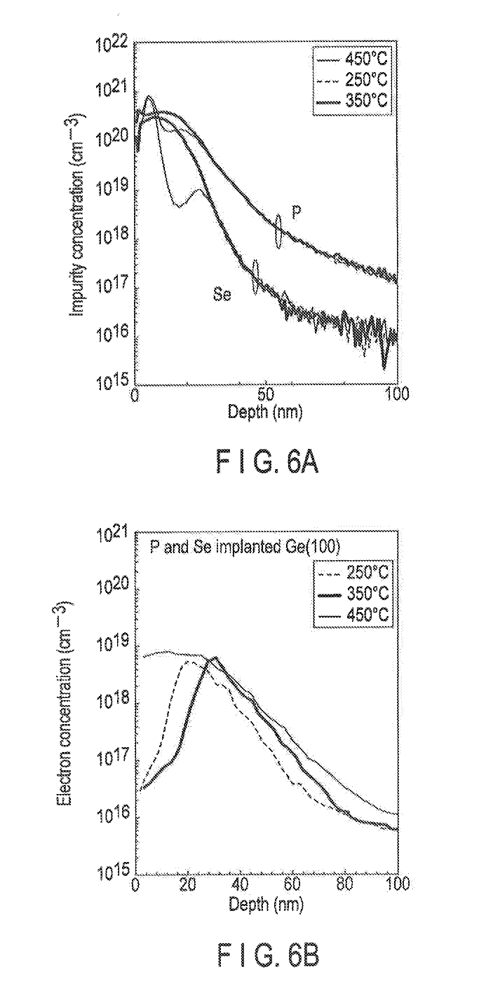

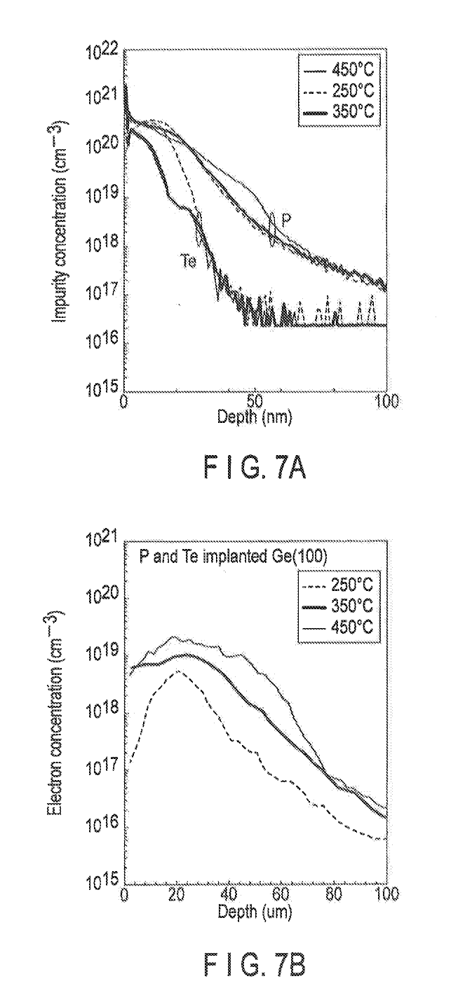

Similarly, also for cases of other chalcogens introduced along with P, it was found that the electron concentration increased also at a low temperature as shown in FIGS. 6A, 6B, 7A, and 7B. FIGS. 6A and 6B are for cases of Se implanted into a Ge substrate along with P; FIG. 6A shows a profile of an impurity concentration; and FIG. 6B shows a profile of an electron concentration. FIGS. 7A and 7B are for cases of Te implanted into a Ge substrate along with P; FIG. 7A shows a profile of an impurity concentration, and FIG. 7B shows a profile of an electron concentration. The acceleration energies for Sc and Te were 17 and 20 keV, respectively, in order to allow the projected range to match P injection, and the doses were 5×10¹⁴ cm⁻², which is the same as S.

Thus, introducing a chalcogen (S, Sc, or Te) into a Ge substrate along with P as an n-type impurity can increase an electron concentration in an n-type impurity diffusion area sufficiently at a temperature lower than 450° C., such as 250° C. Applying this to a MOSFET or another semiconductor device can make a contribution to improvement in characteristics of the device. Note that the impurity concentration of the chalcogen is desirably lower than the n-type impurity concentration.

The inventors also found that implanting all three kinds of chalcogens (S, Se, and Te) could form an n⁺-Ge layer with a high concentration even without introducing typical n-type impurity, such as P.

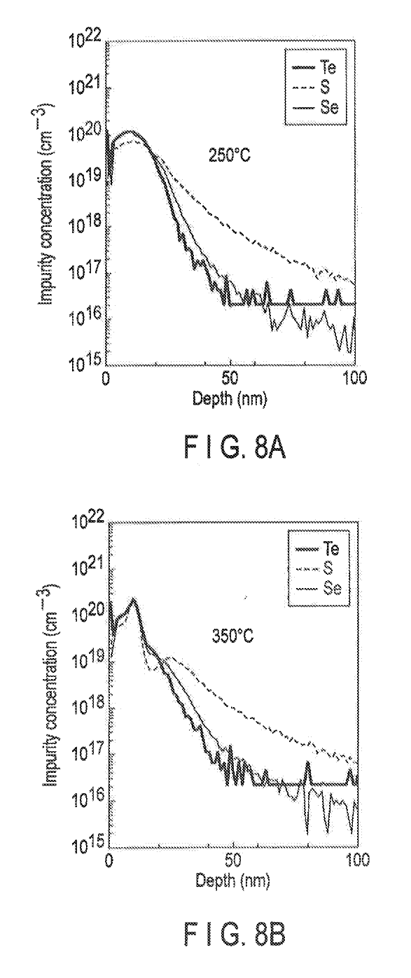

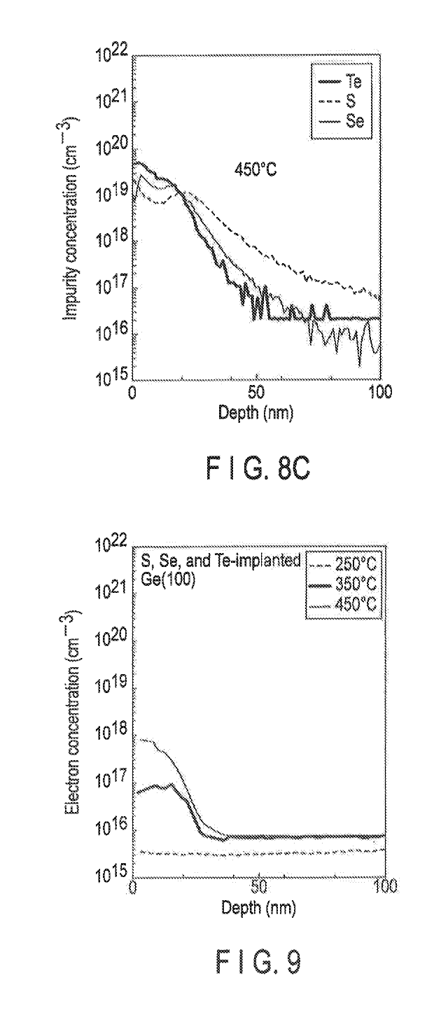

FIGS. 8A to 8C are figures showing the impurity profiles with various heat treatment temperatures with S, Se, and Te. FIG. 8A is for 250° C., FIG. 8B is for 350° C., and FIG. 8C is for 450° C. As can be seen from these figures, the impurity profiles with various heat treatment temperatures hardly change except for a vicinity of the surface as in the case of S, Se, and Te introduced independently. That is, it can be seen that diffusion does not occur except for a vicinity of the surface.

FIG. 9 is a figure showing a profile of an electron concentration of a Ge substrate with three kinds of ions of S, Se, and Te implanted. Increase in the electron concentration is hardly seen at 250° C.; however steep increases in electron concentration are seen up to a depth of about 20 nm from the surface at 350° C. and 450° C. That is, it can be seen that only a single chalcogen will result in no observation of increase in electron concentration through a heat treatment or only formation of an n⁺-Ge layer of a low-concentration, but introducing all of them will result in a higher electron concentration with a higher temperature for a heat treatment after the ion implantation. In particular, it can be seen that the electron concentration greatly increases above 350° C. The maximum concentration at 350° C. was 8.1×10¹⁷ cm⁻³, and the maximum concentration at 450° C. was 9.35×10¹⁶ m⁻³.

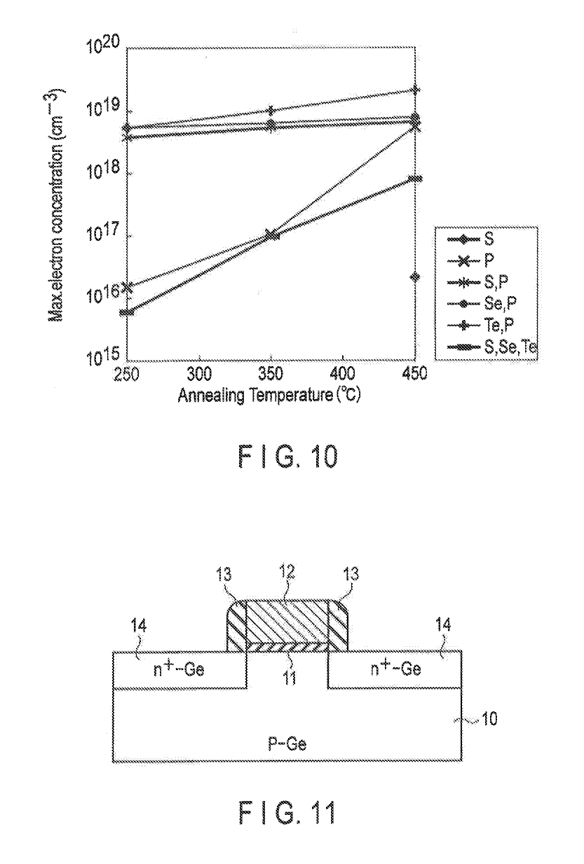

When summarized, the maximum electron concentration (cm⁻³) in each case is as shown in the following Table 1 and FIG. 10.

TABLE 1

| | 250° C. | 350° C. | 450° C. |
|---|---|---|---|
| S | — | — | 2.13 × 10¹⁶ |
| Se | — | — | — |
| Te | — | — | — |
| P | 1.5 × 10¹⁶ | 1.03 × 10¹⁷ | 5.65 × 10¹⁸ |
| S, P | 3.76 × 10¹⁸ | 5.31 × 10¹⁸ | 6.91 × 10¹⁸ |
| Se, P | 5.37 × 10¹⁸ | 6.23 × 10¹⁸ | 7.88 × 10¹⁸ |
| Te, P | 5.31 × 10¹⁸ | 1.01 × 10¹⁸ | 2.16 × 10¹⁹ |
| S, Se, Te | 5.73 × 10¹⁵ | 9.35 × 10¹⁶ | 8.13 × 10¹⁷ |

Unit: cm⁻³

Thus, implanting all three kinds of chalcogen (S, Se, and Te) can increase an electron concentration in an n-type impurity diffusion area sufficiently at a temperature lower than 450° C., such as 350° C. Applying this to a MOSFET or another semiconductor device can contribute to improvement in characteristics of the device.

The description has been made of an example with P used as an n-type impurity; however the same advantages are expected also when other n-type impurities, such as As and Sb, are used. Moreover, when “n” is replaced with “p” and the n-type impurity is replaced with the p-type impurity in the above description, it is applicable not only to formation of an n⁺ layer but formation a p+ layer.

Description has been also made of, as a semiconductor, a semiconductor with Ge as the main ingredient; however the semiconductor could also be Si or a compound semiconductor, such as GaAs, InP, InSb, GaN, InGaAs, etc. of III-V group semiconductors, and any semiconductor is applicable.

In a GaAs material, Zn is used as a p-type impurity and Si is used as an n-type impurity, for example, and introducing them with one or more kinds of chalcogens can form a high concentration layer of respective conductivity types. Moreover, description has been made of a case of 5×10¹⁴ cm⁻² as a dose of each chalcogen; however the advantages of the embodiments can be obtained as long as the solid solubility limit of the chalcogen is exceeded in a semiconductor layer. For example, only 1×10¹⁶ cm⁻³ or more is necessary for a Ge substrate.

A temperature used to electrically-activate an impurity differs for every semiconductor, and, based on the embodiments below, a lower temperature or reduction in time can be achieved. A heat treatment for electrical activation may cause diffusion of the impurity, which can be suppressed by the reduction in temperature or time for the heat treatment.

Specific embodiments to which the techniques described above are applied will now be described.

### First Embodiment

FIG. 11 is a sectional view showing a schematic structure of a Ge-MOSFET according to the first embodiment. In the figure, 10 is a p-Ge substrate, and on the surface of this substrate 10 a gate electrode 12 of, for example, polycrystalline silicon is formed, with a gate insulating film 11 of, for example, silicon oxide, interposed therebetween. On both sides of the gate electrode 12, sidewall insulating films 13 are formed. In the surface area of the substrate 10, source/drain areas 14 (S/D areas) of n⁺ diffusion areas are formed to sandwich the gate structure.

In the S/D areas 14, P as an n-type impurity and Te as a chalcogen are introduced by the ion implantation as will be described later. The impurity is activated by annealing after the ion implantation to result in formation of n⁺ type impurity diffusion areas with a high electron concentration.

In a MOSFET with the gate length of 50 nm, the thickness of the substrate direction of an S/D area 14 is about a third of the gate length (10 to 20 nm); the maximum impurity concentration of P is 3×10¹⁹ m⁻³; and the maximum impurity concentration of Te is lower than it and 2×10¹⁹ cm⁻³. These impurity concentrations may be higher as long as Te does not exceed the concentration of P. A temperature for a heat treatment is 350° C., which can increase the carrier concentration without degrading the structure of the gate insulating film and substrate. Even such a temperature can sufficiently activate the impurity to realize good characteristics of a device.

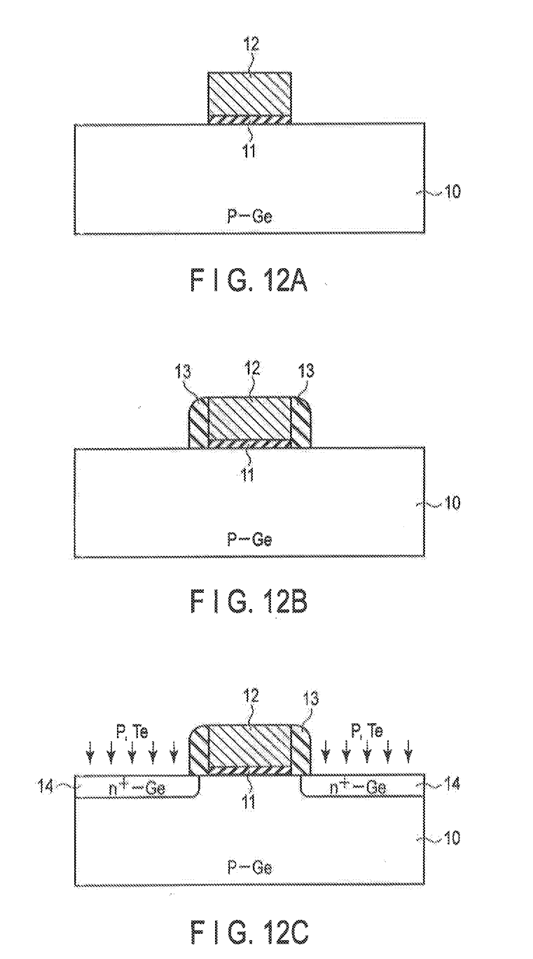

FIGS. 12A to 12C are sectional views showing a manufacturing process of the Ge-MOSFET of the present embodiment.

First, as shown in FIG. 12A, on the surface of the p-Ge substrate 10, the gate electrode 12 is formed with the gate insulating film 11 interposed therebetween.

Specifically, on the surface of the substrate 10, a silicon oxide is formed and then a polysilicon film is deposited, and then they are processed into a gate pattern.

Subsequently, as shown in FIG. 12B, the sidewall insulating films 13 are formed on both side surfaces of the gate electrode 12. For forming the sidewall insulating films 13, for example, a silicon oxide may be deposited on the whole surface and then etched back to remove part thereof on the surface of the substrate and the top surface of the gate electrode.

Subsequently, as shown in FIG. 12C, the gate electrode 12 and the sidewall insulating films 13 are used as a mask to introduce P and Te into the surface area of the substrate 10 by ion implantation to form the S/D areas 14. As for the order of the ion implantation, any of P and Te may precede the other. The depth of the ion implantation to a MOSFET with the gate length of 50 nm is about a third of the gate length (10 to 20 nm), and the maximum impurity concentration of P is 3×10¹⁹ cm⁻³, and the maximum impurity concentration of Te is lower than this, at 2×10¹⁹ cm⁻³.

Subsequently, an annealing treatment is performed at a temperature of, for example, 350° C.; as a result, the carrier concentration of the n⁺ type diffusion layers (S/D areas) 14 could be increased without degrading the structure of the gate insulating film and the substrate. The carrier concentration of the polysilicon layer can also be increased. The gate electrode has been described as an example of the polysilicon film; however it may be another polycrystalline semiconductor or a metal. In a case of the polycrystalline semiconductor, the carrier concentration can be increased via the advantages achieved by the present study.

After this, deposition of interlayer dielectric films, etc., (not shown) and formation of contact plugs will result in completion of the Ge-MOSFET.

Thus, in the present embodiment, introducing P as an n-type impurity and Te as a chalcogen for forming the S/Ds to utilize the phenomenon in which the electron concentration increases after a heat treatment can form high concentration n⁺-Ge layers. In this case, the anneal temperature for activating the impurity can be lower than in the case of P being independently introduced, which can suppress an increase of level of the interface between the gate insulating film and Ge substrate due to the annealing. Therefore, the characteristics of the Ge-MOSFET device can be improved.

### Second Embodiment

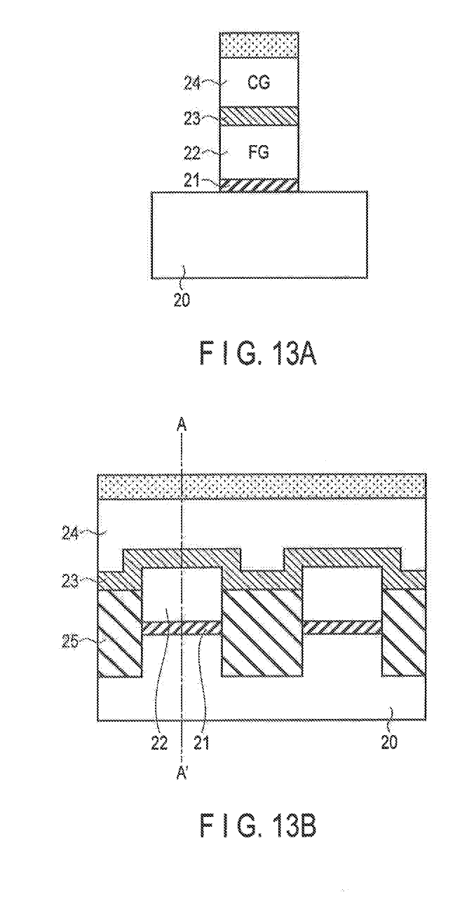

FIGS. 13A and 13B are sectional views showing a schematic structure of a nonvolatile semiconductor memory device according to the second embodiment, and FIG. 13A corresponds to section A-A′ of FIG. 13B.

On a Si substrate 20, a floating gate (charge storage layer) 22 is formed with a tunnel insulating film 21 interposed therebetween. On the floating gate 22, a control gate 24 is formed with an inter-electrode insulating film 23 interposed therebetween. In the substrate 20, trenches are formed along a word line direction, and element isolation insulating films 25 are formed in these trenches. The upper surfaces of the element isolation insulating films 25 are higher than the bottom surfaces of the floating gates 22, and lower than the top surfaces of the floating gates 22.

Also in such a structure, S, Se, or Te of a chalcogen is introduced into the floating gates 22 and the control gate 24 in addition to P as in the first embodiment, which allows for activation of the impurity by the annealing at a low temperature. This can suppress the resistances of the floating gates 22 and the control gate 24 to be small to improve characteristics of the device.

### Third Embodiment

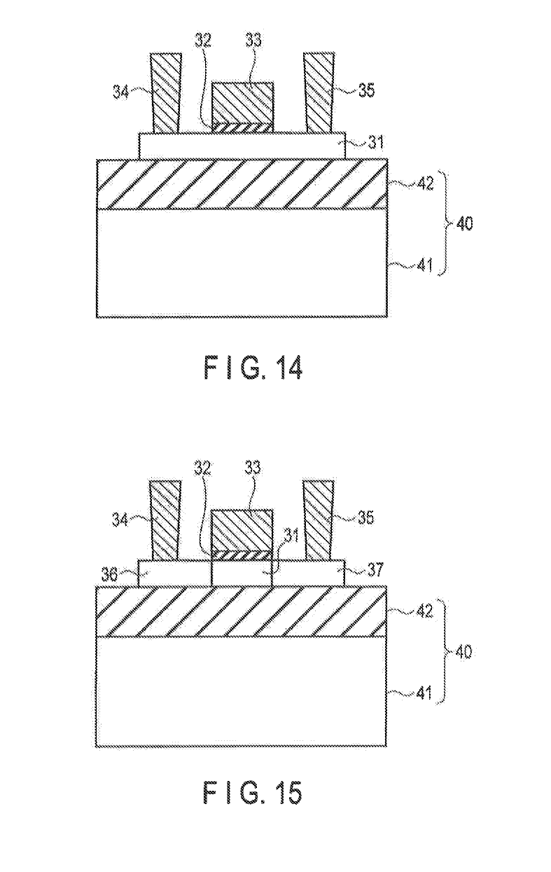

FIG. 14 is a schematic structure figure showing a junctionless transistor according to the third embodiment.

On a support substrate 40 in which an insulating film 42 is formed on an Si substrate 41, an n⁺-Ge layer 31 is formed. On the n⁺-Ge layer 31, a gate electrode 33 is formed with a gate insulating film 32 interposed therebetween. On the surface of the n⁺-Ge layer 31, source/drain electrodes 34 and 35 are formed to sandwich the gate electrode 33.

Such a junctionless transistor is a nanoscale MOS transistor structured without a pr junction. All of the areas of a source, channel, and drain are configured from a semiconductor layer of the same polarity, and therefore it requires a device structure with a significantly high gate electrostatic control ability to realize an OFF state. For this reason, it is desirable to form the n⁺-Ge layer 31 in a fin shape on the insulator 42 and to form the gate electrode 33 to surround the n⁺-Ge layer 31.

The source drain areas are not necessarily the n⁺-Ge layer 31, which is the case for the channel, and the entirety of the source drain areas or the upper part of the n⁺-Ge layer 31 may be layers 36 and 37 of metal, such as NiGe, as shown in FIG. 15.

In such a junctionless transistor, P and S are ion-implanted in the Ge layer and then anneal is performed at a temperature of 350° C. to form the n⁺-Ge layer 31.

Alternatively, epitaxial growth with P and B introduction forms the n⁺-Ge layer 31. Thereby, the impurity of the Ge layer 31 can be high in electron concentration, and characteristics of the device can be improved.

### Modification

The embodiments are not limited to those described above.

In the embodiments, description has been made of the example of P used as an n-type impurity; however the same advantages are also expected with other n-type impurities, such as As and Sb. Moreover, formation of an n⁺ layer is not the only case, and application to formation of p+ layer is also possible. The method of introducing an impurity is not limited to the ion implantation but may be, for example, epitaxial growth, solid phase diffusion, or gaseous phase diffusion, etc.

Moreover, the semiconductor is not limited to a semiconductor layer with G as the main ingredient or a Si layer, but may be a compound semiconductor. Furthermore, application not only to the source/drain areas and extension layers of MOSFETs, the control gate electrodes and floating gate electrodes of nonvolatile semiconductor devices (floating gate type, MONOS type, etc.), and the substrate of functionless transistors, etc., but also to areas where high carrier concentrations need to be formed is possible.

While certain embodiments have been described, these embodiments have been presented by way of example only, and are not intended to limit the scope of the inventions. Indeed, the novel embodiments described herein may be embodied in a variety of other form furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device of a junctionless structure comprising:
a semiconductor layer of a first conductivity type;
a pair of source/drain electrodes at a distance on the semiconductor layer;
a gate insulating film on the semiconductor layer between the source/drain electrodes;
a gate electrode on the gate insulating film,
wherein the semiconductor layer has two or more kinds of impurities, one kind of the two or more kinds of impurities is an element selected from a group of chalcogens, and another kind of the two or more kinds of impurities is a first conductivity type impurity.

2. The device of claim 1, wherein the first conductivity is an n-type, and the group of chalcogens is S, Se and Te.

3. The device of claim 2, wherein the semiconductor layer is a Ge layer, and the first conductivity type impurity is P.

4. The device of claim 1, further comprising metal layers between the semiconductor layer and the source/drain electrodes.

5. A semiconductor device comprising:
a semiconductor layer of a first conductivity type;
a pair of source/drain electrodes at a distance on the semiconductor layer;
a gate insulating film on the semiconductor layer between the source/drain electrodes;
a gate electrode on the gate insulating film,
wherein the semiconductor layer has two or more kinds of impurities, one kind of the two or more kinds of impurities is an element selected from a group of chalcogens, another kind of the two or more kinds of impurities is a first conductivity type impurity, the semiconductor layer is of the first conductivity type below the gate insulating film and below the source/drain electrodes.

6. The device of claim 5, wherein the first conductivity is an n-type, and the group of chalcogens is S, Se and Te.

7. The device of claim 6, wherein the semiconductor layer is a Ge layer, and the first conductivity type impurity is P.

8. The device of claim 5, further comprising metal layers between the semiconductor layer and the source/drain electrodes.

9. A method of manufacturing a semiconductor device, comprising:
forming a semiconductor layer of a first conductivity type, the semiconductor layer having two or more kinds of impurities, one kind of the two or more kinds of impurities being an element selected from a group of chalcogens, and another kind of the two or more kinds of impurities being a first conductivity type impurity;
forming a gate insulating film on the semiconductor layer;
forming a gate electrode on the gate insulating film; and
forming a pair of source/drain electrodes on the semiconductor layer at both sides of the gate electrode.

10. The method of claim 9, wherein forming a semiconductor layer comprises:
introducing the element selected from the group of chalcogens and the first conductivity type impurity into the semiconductor layer; and
performing a heat treatment to the semiconductor layer to activate the introduced impurity.

11. The method of claim 9, wherein the first conductivity type is an n-type, and the group of chalcogens is S, Se and Te

12. The method of claim 11, wherein the semiconductor layer is a Ge layer, and the first conductivity type impurity is P.

13. The method of claim 9, further comprising forming metal layers between the semiconductor layer and the source/drain electrodes.
